(19) United States
(12) Patent Application Publication
(10) Pub. No.: US 2014/0120661 A1
(43) Pub. Date: May 1, 2014

(54) FLIP CHIP PACKAGING METHOD

(71) Applicant: Silergy Semiconductor Technology (Hangzhou) LTD, Hangzhou (CN)

(72) Inventor: Xiaochun Tan, Hangzhou (CN)

(73) Assignee: Silergy Semiconductor Technology (Hangzhou) LTD, Hangzhou (CN)

(21) Appl. No.: 13/975,511

(22) Filed: Aug. 26, 2013

(30) Foreign Application Priority Data
Oct. 31, 2012 (CN) 201210428121.7

(51) Int. Cl. H01L 23/00

(52) U.S. Cl. CPC H01L 24/83
USPC 438/108

(57) ABSTRACT

Disclosed are various flip chip packaging methods. In one embodiment, a method can include: (i) arranging a plurality of pads on a chip; (ii) arranging a plurality of first connecting structures on the plurality of pads, where each of the first connecting structures comprises a first metal; (iii) arranging a plurality of second connecting structures on the plurality of first connecting structures, where each second connecting structure comprises a second metal, and where a hardness of the first metal is less than a hardness of the second metal; and (iv) flipping the chip with the first and second connecting structures and arranging corresponding of the second connecting structures on pads of a substrate to form electrical connection between the chip and the substrate via the first and second connecting structures.

### RELATED APPLICATIONS

This application claims the benefit of Chinese Patent Application No. 201210428121.7, filed on Oct. 31, 2012, which is incorporated herein by reference in its entirety.

### FIELD OF THE INVENTION

The present invention relates to the field of manufacturing semiconductor devices, and more particularly to a flip chip packaging method.

### BACKGROUND

A developing trend in electronic packaging is toward smaller and lighter packages, and flip chip packaging technology is arising in line with this developing trend. As compared to more traditional packaging approaches with lead connections, flip chip packaging technology has advantages of high packaging density, good electric and thermal performance, and high reliability. Conventional flip chip packaging technology can realize electrical and mechanical connections by inverting the chip, and by placing the chip on a substrate or printed-circuit board (PCB) via solder joints.

### SUMMARY

In one embodiment, a flip chip packaging method can include: (i) arranging a plurality of pads on a chip; (ii) arranging a plurality of first connecting structures on the plurality of pads, where each of the first connecting structures comprises a first metal; (iii) arranging a plurality of second connecting structures on the plurality of first connecting structures, where each second connecting structure comprises a second metal, and where a hardness of the first metal is less than a hardness of the second metal; and (iv) flipping the chip with the first and second connecting structures and arranging corresponding of the second connecting structures on pads of a substrate to form electrical connection between the chip and the substrate via the first and second connecting structures.

In one embodiment, a flip chip packaging method can include: (i) arranging a plurality of pads on a substrate; (ii) arranging a plurality of first connecting structures on the plurality of pads, where each of the first connecting structures comprises a first metal; (iii) arranging a plurality of second connecting structures on the plurality of first connecting structures, where each second connecting structure comprises a second metal, and where a hardness of the first metal is less than a hardness of the second metal; and (iv) flipping a chip and arranging pads of the chip on corresponding of the second connecting structures to form electrical connection between the chip and the substrate via the first and second connecting structures.

Embodiments of the present invention can provide several advantages over conventional approaches, as may become readily apparent from the detailed description of preferred embodiments below.

### BRIEF DESCRIPTION OF THE DRAWINGS

FIG. 1A shows a structure diagram of an example flip chip packaging device.

FIG. 1B is a flow diagram of a first example flip chip packaging method, in accordance with embodiments of the present invention.

FIG. 2A to FIG. 2I are structure diagrams of example steps of the flip chip packaging method of FIG. 1B, in accordance with embodiments of the present invention.

FIG. 3 is a flow diagram of a second example flip chip packaging method, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set fourth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

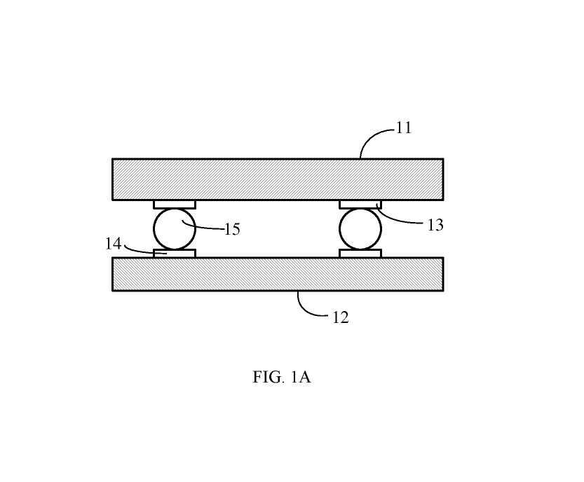

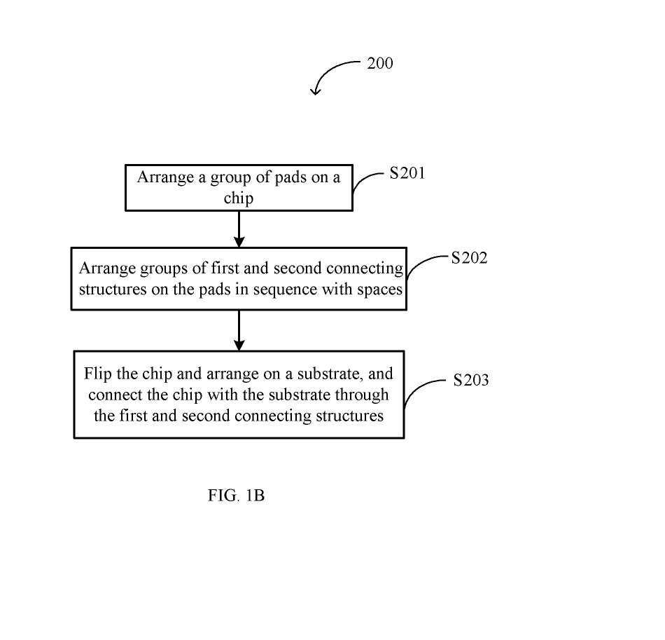

Referring now to FIG. 1A, shown is a structure diagram of an example flip chip packaging device. This flip chip packaging device can include chip 11, substrate 12, chip pads 13, substrate pads 14, and solder balls 15. Chip pads 13 can be placed on an upper surface of chip 11 in order to “lead out” or accommodate an external chip connection, such as to form a chip electrode. A solder ball 15 can be placed between a chip pad 13 and a substrate pad 14 to lead out an electrode of chip 11 through substrate 12.

However, the thermal expansion coefficients of chip 11 and substrate 12 may be different. Thus, when temperature changes, deformation can occur on solder balls 15. Further, such deformation can relate to the height of a solder ball, the chip size, the substrate thickness, and other factors. For example, deformation on solder ball 15 may cause fatigue fracture of the solder ball and in some cases an associated electrical open or short circuit, possibly resulting in system failure.

In particular embodiments, a flip chip packaging method can include arranging a group of first connecting structures and a group of second connecting structures on pads of a chip. The connecting structures can be arranged in sequence (e.g., the first group of connecting structures prior to the second group of connecting structures), and with spaces therebetween, where the spaces correspond to pads on the chip. The chip with the first and second connecting structures can then be “reversely arranged” or flipped such that the second connecting structures can align with corresponding pads on a substrate. In this way, the chip can be electrically connected with the substrate through the first and second connecting structures. Further, a flip chip packaging device can bear thermal stresses that may result from different thermal expansion coefficients of the chip and the substrate, where such thermal stress can result in deformation of a solder ball. In this way, a solder ball can be effectively prevented from suffering from fatigue fracture, and the thermal stress reliability of the flip chip package can be improved.

In one embodiment, a flip chip packaging method can include: (i) arranging a plurality of pads on a chip; (ii) arranging a plurality of first connecting structures on the plurality of pads, where each of the first connecting structures comprises a first metal; (iii) arranging a plurality of second connecting structures on the plurality of first connecting structures, where each second connecting structure comprises a second metal, and where a hardness of the first metal is less than a hardness of the second metal; and (iv) flipping the chip with the first and second connecting structures and arranging corresponding of the second connecting structures on pads of a substrate to form electrical connection between the chip and the substrate via the first and second connecting structures.

Referring now to FIG. 1B, shown is a flow diagram of a first example flip chip packaging method, in accordance with embodiments of the present invention. In this particular example, flip chip packaging method 200 can include arranging a group of pads on a chip at S201. The pads can be placed on a surface of the chip to lead out or allow electrical connection to an external chip node (e.g., a control signal, and I/O signal, etc.). At S202, a group of first connecting structures and a group of second connecting structures can be arranged on the pads in sequence with spaces. For example, the first connecting structures can be arranged on the pads of the chip, and then the second connecting structures can be arranged on an aligned with the first connecting structures. Thus, a stack of two connecting structures can be formed on the each chip pad that is to be externally connected.

The first connecting structures can include a first metal, and the second connecting structures can include a second metal. Also, a “hardness” of the first metal may be less than the hardness of the second metal. For example, the first connecting structures can be formed by a metal (e.g., gold, silver, aluminum, etc.) with a relatively low hardness. In addition, the second connecting structures can be formed by a different metal (e.g., copper, nickel, copper alloy etc.) with a relatively high hardness. Hardness is a measure of how resistant solid matter is to various kinds of permanent shape change when a force is applied.

At S203, the chip may be flipped and reversely arranged or aligned on a substrate, where the chip can be electrically connected with the substrate through the first and second connecting structures. An electrical connection can be made between the first and second connecting structures and corresponding pads of the chip and the substrate.

The first and/or the second connecting structures can be formed by any suitable process, such as a wire bonding process or an electroplating process. In a wire bonding process, the bond wires can be passed through a capillary of a bonder chopper and extended. A hydrogen-oxygen flame or an electric spark discharge system can be used to generate an electric spark to melt a protruding portion of the bond wire outside the chopper of the wires. The molten metal can then be solidified to form standard balls under surface tension action. By lowering the chopper, and pressing the metal balls on the chip under appropriate pressure and within an appropriate time, a first such wire bonding may be completed. Then, the chopper can be moved to a position of a next bonding, and so forth until each solder ball is created.

For example, the first connecting structures and/or the second connecting structures can be formed by a wire bonding process. Such a wire bonding process can include making a first bonding as described above. Then, wires can be cut off after forming solder balls to form the first and/or the second connecting structures. In particular embodiments, the first and/or the second connecting structures formed by such a wire bonding process can be spherical in shape.

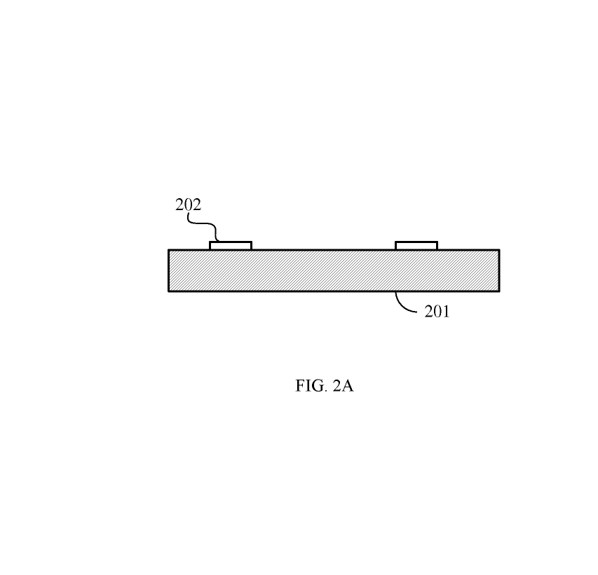

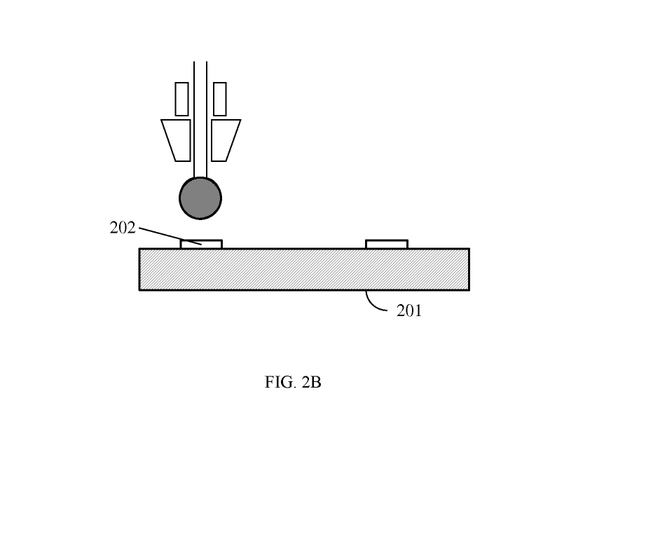

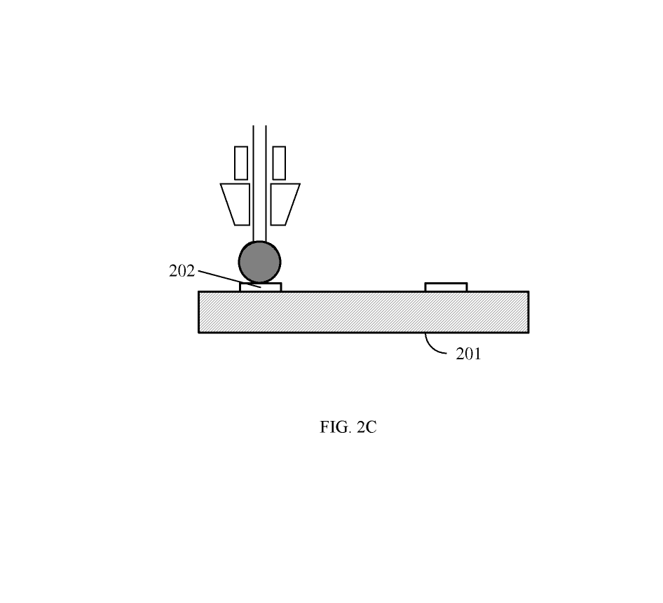

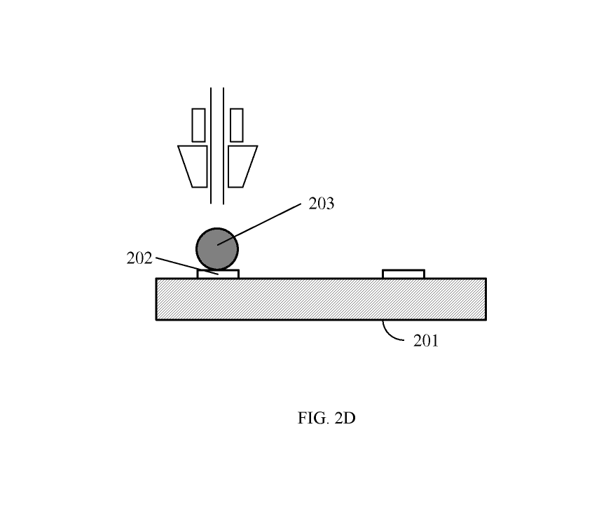

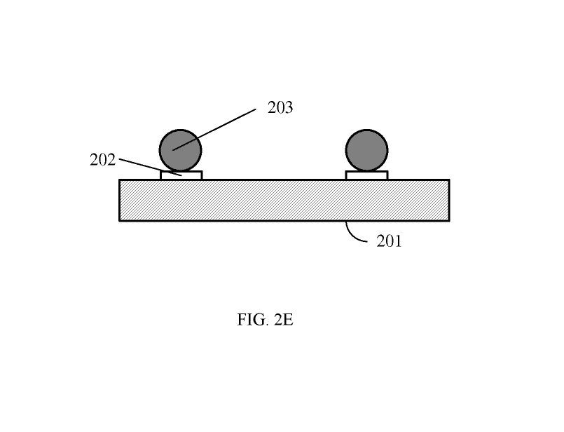

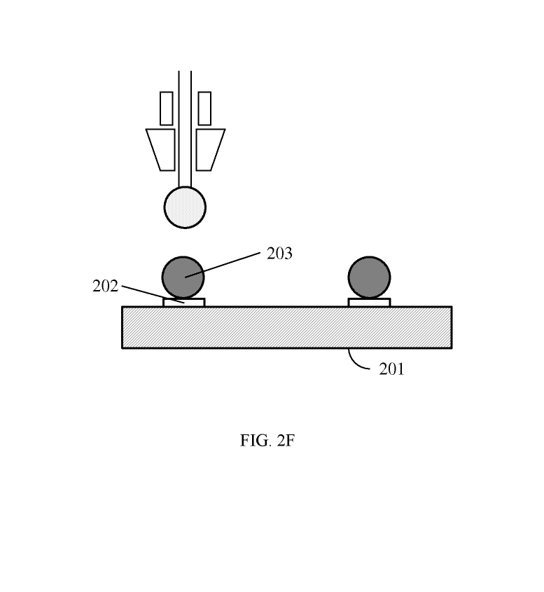

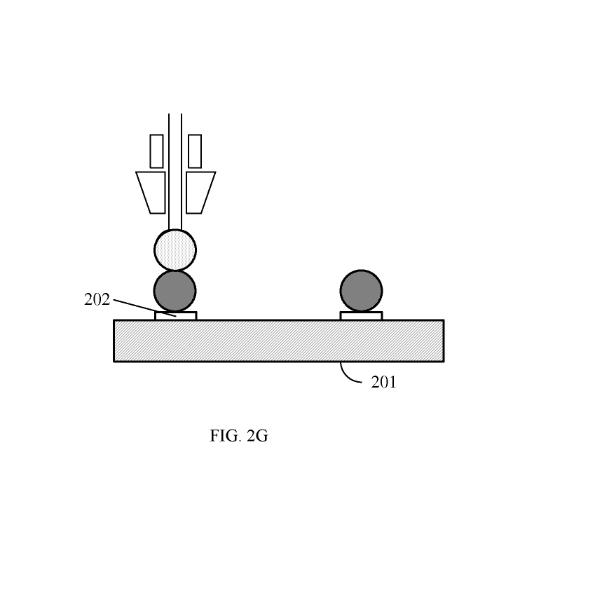

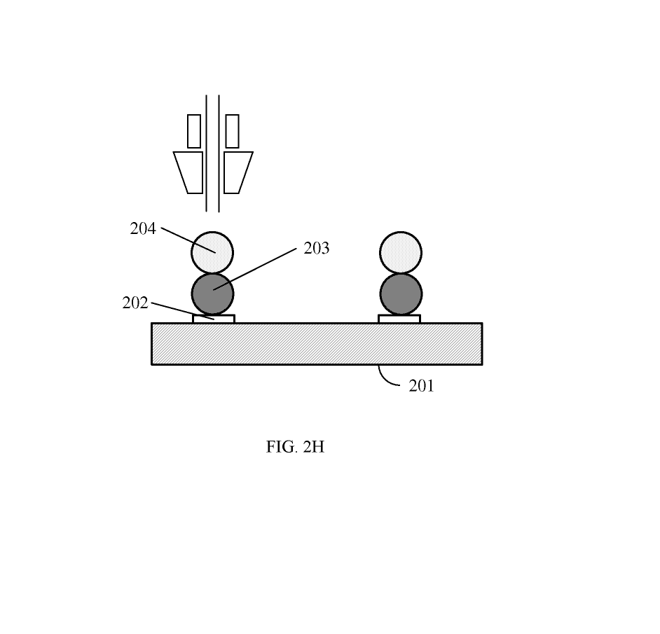

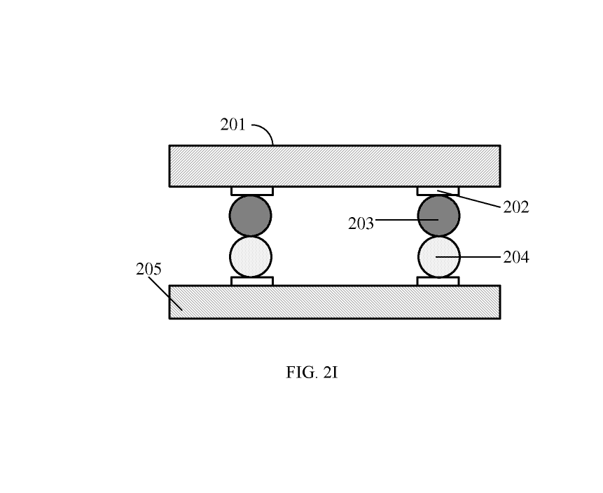

Referring now to FIGS. 2A to 2I, shown are structure diagrams showing an example flip chip packaging method, in accordance with embodiments of the present invention. This example flip chip packaging method can correspond to the flow shown above in FIG. 1B. In FIG. 2A, a group of pads 202 can be arranged on a surface (e.g., a top surface) of chip 201. In FIGS. 2B and 2C, a first bonding of a wire bonding process can be formed.

In FIG. 2D, bond wire extensions can be cut off to form the first connecting structures (e.g., solder balls 203). Similarly, other solder balls 203 can be formed on other pads 202, as shown in FIG. 2E. For example, solder balls 203 can selectively include copper or a copper alloy. The second connecting structures can be formed in a similar fashion as shown in FIGS. 2E, 2F, 2G, and 2H. In this way, solder balls 204 can be aligned and formed on each of solder balls 203. For example, solder balls 204 can include gold or a gold alloy. In FIG. 2I, chip 201 can be flipped and arranged on substrate 205 such that the pads of chip 201 and substrate 205 may be electrically connected through solder balls 203 and 204.

The first connecting structures (e.g., solder balls 203) and/or the second connecting structures (e.g., solder balls 204) can be formed through an electroplating process. The first and/or the second connecting structures formed by an electroplating process can be in a convex block structure (e.g., cylindrical shape). Also, either order of the “first” and “second” connecting structures can be arranged relative to the chip and substrate to be connected therewith. For example, the second connecting structures with relatively high hardness can be directly placed on pads of the chip, with the first connecting structures being aligned and placed on or above the second connecting structures.

Also, another group of pads can be placed on the substrate for connecting the first and/or the second connecting structures. When the temperature is changing, deformation can result due to differences in the thermal expansion coefficients of the chip and the substrate. However, since the hardness of the first connecting structures may be relatively low, the first connecting structures can bear the thermal stress deformation well through the deformation itself. This may avoid possible fracture of the chip, the substrate, or the connecting structures, or separation from each other, and may avoid possible circuit open or short conditions, in order to improve system reliability. Further, because of the relatively good conductive performance of the second connecting structures, a flip chip package made from a packaging method of particular embodiments can achieve suitable electrical connectivity between the chip and the substrate (e.g., a printed-circuit board [PCB]).

In one embodiment, a flip chip packaging method can include: (i) arranging a plurality of pads on a substrate; (ii) arranging a plurality of first connecting structures on the plurality of pads, where each of the first connecting structures comprises a first metal; (iii) arranging a plurality of second connecting structures on the plurality of first connecting structures, where each second connecting structure comprises a second metal, and where a hardness of the first metal is less than a hardness of the second metal; and (iv) flipping a chip and arranging pads of the chip on corresponding of the second connecting structures to form electrical connection between the chip and the substrate via the first and second connecting structures.

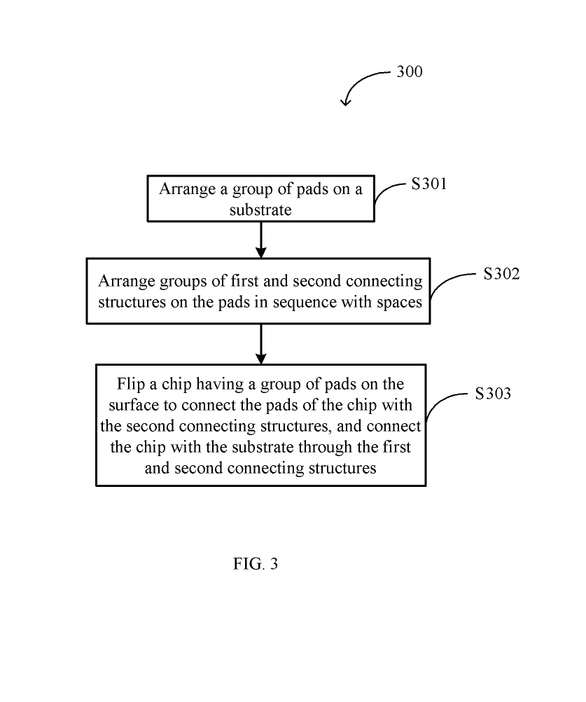

Referring now to FIG. 3, shown is a flow diagram of a second example flip chip packaging method in accordance with embodiments of the present invention. This particular example flip chip packaging method 300 can include arranging a group of pads on a substrate at S301. The pads can be positioned on the surface of the substrate to accommodate electrical connection between the substrate and the chip. At S302, a group of first connecting structures and a group of second connecting structures can be arranged on the pads in sequence with spaces. Here, the first connecting structures can include a first metal, and the second connecting structures can include a second metal. For example, the hardness of the first metal (e.g., gold, silver, aluminum, etc.) may be less than the hardness of the second metal (e.g., copper, nickel, copper alloy, etc.).

At S303, a chip having a group of pads on the surface can be flipped and aligned to connect pads on the surface of the chip with the second connecting structures. The chip may be electrically connected with the substrate through the first and the second connecting structures. The first and/or the second connecting structures can be formed by wire bonding process, or an electroplating process, as discussed above.

The embodiments were chosen and described in order to best explain the principles of the invention and its practical applications, to thereby enable others skilled in the art to best utilize the invention and various embodiments with modifications as are suited to the particular use contemplated. It is intended that the scope of the invention be defined by the claims appended hereto and their equivalents.

What is claimed is:

1. A flip chip packaging method, comprising:
a) arranging a plurality of pads on a chip;
b) arranging a plurality of first connecting structures on said plurality of pads, wherein each of said first connecting structures comprises a first metal;
c) arranging a plurality of second connecting structures on said plurality of first connecting structures, wherein each second connecting structure comprises a second metal, and wherein a hardness of said first metal is less than a hardness of said second metal; and
d) flipping said chip with said first and second connecting structures and arranging corresponding of said second connecting structures on pads of a substrate to form electrical connection between said chip and said substrate via said first and second connecting structures.

2. The method of claim 1, wherein each of said plurality of first connecting structures comprises gold.

3. The method of claim 1, wherein each of said plurality of first connecting structures comprises silver.

4. The method of claim 1, wherein each of said plurality of second connecting structures comprises copper.

5. The method of claim 1, wherein each of said plurality of second connecting structures comprises nickel.

6. The method of claim 1, wherein each of said first and second connecting structures are formed using a wire bonding process, wherein said wire bonding process comprises:
a) making a first bonding of a plurality of wires; and
b) cutting off each of said plurality of wires to form a connecting structure.

7. The method of claim 1, wherein each of said plurality of first connecting structures is formed through an electroplating process.

8. The method of claim 1, wherein each of said plurality of second connecting structures is formed through an electroplating process.

9. A flip chip packaging method, comprising:
a) arranging a plurality of pads on a substrate;
b) arranging a plurality of first connecting structures on said plurality of pads, wherein each of said first connecting structures comprises a first metal;
c) arranging a plurality of second connecting structures on said plurality of first connecting structures, wherein each second connecting structure comprises a second metal, and wherein a hardness of said first metal is less than a hardness of said second metal; and
d) flipping a chip and arranging pads of said chip on corresponding of said second connecting structures to form electrical connection between said chip and said substrate via said first and second connecting structures.

10. The method of claim 9, wherein each of said plurality of first connecting structures comprises gold.

11. The method of claim 9, wherein each of said plurality of first connecting structures comprises silver.

12. The method of claim 9, wherein each of said plurality of second connecting structures comprises copper.

13. The method of claim 9, wherein each of said plurality of second connecting structures comprises nickel.

14. The method of claim 9, wherein each of said first and second connecting structures are formed using a wire bonding process, wherein said wire bonding process comprises:
a) making a first bonding of a plurality of wires; and
b) cutting off each of said plurality of wires to form a connecting structure.

15. The method of claim 9, wherein each of said plurality of first connecting structures is formed through an electroplating process.

16. The method of claim 9, wherein each of said plurality of second connecting structures is formed through an electroplating process.
